(19) United States
(12) Patent Application Publication
(10) Pub. No.: US 2026/0092965 A1
(43) Pub. Date: Apr. 2, 2026

(54) SCANDUMP SIMULATION AND CO-SIMULATION FOR DEVICE TESTING

(71) Applicant: Samsung Electronics Co., Ltd., Suwon-si (KR)

(72) Inventors: Chunlin WANG, Cupertino, CA (US); Dongwoon KIM, Austin, TX (US)

(21) Appl. No.: 19/026,354

(22) Filed: Jan. 16, 2025

Related U.S. Application Data
(60) Provisional application No. 63/701,535, filed on Sep. 30, 2024.

(51) Int. Cl. G01R 31/28; G01R 31/317; G01R 31/3185

(52) U.S. Cl. CPC G01R 31/2848; G01R 31/31725; G01R 31/318544

(57) ABSTRACT

A system and a method for an integrated test circuit are described. The test circuit includes an interface circuit and a test controller. The interface circuit is configured to communicate with a device under test to obtain a test scandump from a scandump storage corresponding to an internal circuit of the device. The test controller is configured to generate a test sequence to the interface to control the device and enable a simulation performed by a simulator having a design associated with the device. The test sequence includes identifying a mismatch pattern between a final scan pattern from a final scandump and a simulation pattern from the simulation. The mismatch pattern corresponds to a fault.

### CROSS-REFERENCE TO RELATED APPLICATION

This application claims the priority benefit under 35 U.S.C. § 119(e) of U.S. Provisional Patent Application Serial No. 63/701,535 filed on September 30, 2024, the disclosure of which is incorporated by reference in its entirety as if fully set forth herein.

### TECHNICAL FIELD

The disclosure generally relates to semiconductor testing. More particularly, the subject matter disclosed herein relates to scandump and simulation.

### BACKGROUND

Defects in semiconductor devices are due to a number of reasons. Some examples include encapsulation, die-attach and wire-bond failures and thermal and electrical stress. These defects result in faults on device internal circuits, leading to chip failures or malfunctions. Common faults in semiconductor devices include stuck-at fault and bit flip fault. In a stuck-at fault, a bit in a signal, a register, or a flip-flop is permanently stuck at logical 0 (stuck-at-0) or a logical 1 (stuck-at-1) regardless of the intended signal changes. A bit-flip fault occurs when the value of a single bit changes from a logical 0 to a logical 1 or vice versa unintentionally.

Techniques to detect semiconductor defects include Design for Testability (DFT), Automatic Test Equipment (ATE), automatic test pattern generation (ATPG), and scan chain. These techniques face many problems including inefficiency, long turn-over time, labor intensive work in register transfer level (RTL) review or waveform inspection.

### SUMMARY

To overcome these issues, systems and methods are described herein for a technique of testing semiconductor devices using scandump simulation and co-simulation or hybrid mode. The techniques are efficient and provide useful results in determining faults. In an embodiment, a test circuit includes an interface circuit and a test controller. The interface circuit is configured to communicate with a device under test to obtain a test scandump from a scandump storage corresponding to an internal circuit of the device. The test controller is configured to generate a test sequence to the interface to control the device and enable a simulation performed by a simulator having a design associated with the device. The test sequence includes identifying a mismatch pattern between a final scan pattern from a final scandump and a simulation pattern from the simulation. The mismatch pattern corresponds to a fault.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system according to an embodiment.

FIG. 2 is a diagram illustrating an external test circuit according to an embodiment.

FIG. 3 is a diagram illustrating a comparison a final scan pattern and a simulation pattern according to an embodiment.

FIG. 4 is a diagram illustrating a scandump circuit according to an embodiment.

FIG. 5 is a flowchart illustrating a process of testing with simulation according to an embodiment.

FIG. 6 is a flowchart illustrating the first part of a process of testing with scandump circuit and simulation according to an embodiment.

FIG. 7 is a flowchart illustrating the second part of a process of testing with scandump circuit and simulation according to an embodiment

FIG. 8 is a diagram illustrating a processing system according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures(including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

As used herein, the term “scandump” refers to a snapshot of internal circuit including cell values at a specific location pattern and/or a specific functional test pattern cycle. The scandump data provides observability of internal states of scan circuitry.

As used herein, the term “test circuit” refers to a circuit, a system or apparatus that provides a controlled environment designed to test semiconductor devices. A test circuit may include software and hardware components in an integrated system or as separate elements in a test system. A test circuit may be operated automatically or manually under the control or supervision of a human. A test circuit may operate a device under test (DUT) in a real-time basis or simulate the device based on a design of the DUT.

The disclosure describes a testing technique using simulation. The testing is to locate faults inside a semiconductor device by comparing the actual state of a pattern of an internal circuit with a simulation pattern provided by a simulator given the same stimulus or initial condition. The faults are typically stuck-at faults or bit flip. In one embodiment, the testing employs mainly software operations. In another embodiment, the testing employs a combination of hardware and software in a hybrid configuration. In the software configuration, the test circuit includes an interface circuit and a test controller. The interface circuit is configured to communicate with a device under test to obtain a test scandump from a scandump storage corresponding to an internal circuit of the device. The test controller is configured to generate a test sequence to the interface to control the device and enable a simulation performed by a simulator having a design associated with the device. The test sequence includes identifying a mismatch pattern between a final scan pattern from a final scandump and a simulation pattern from the simulation. The mismatch pattern corresponds to a fault.

In the hybrid configuration, the simulator operates in conjunction with a scandump circuit located inside the device to accommodate the specific internal design of the device. The scandump circuit includes a clock control circuit, a counter, an input gating circuit, an event capture circuit, and a transfer circuit. The clock control circuit is configured to control a clock signal that provides the timing signals to the internal circuit. The counter is configured to assert a stop signal when a count is reached. The counter is clocked by the clock signal. The input gating circuit is configured to capture activities at inputs of the internal circuit in an input enable mode and disable the inputs in an input disable mode. The event capture circuit is configured to capture an event related to the simulation. The transfer circuit is configured to transfer outputs of the internal circuit to the scandump storage.

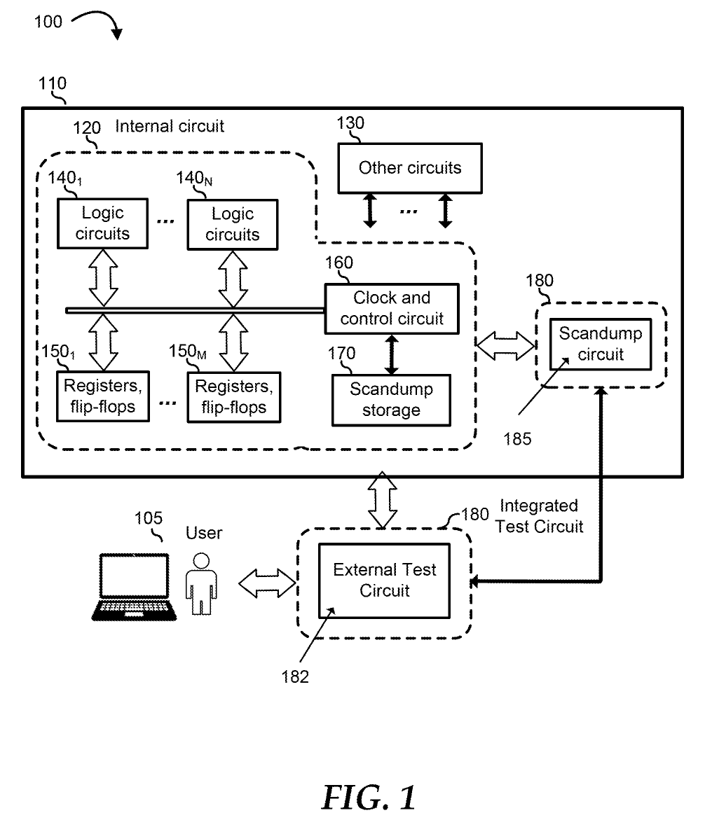

FIG. 1 is a block diagram illustrating a system 100 according to an embodiment. The system 100 represents an environment of a testing process. The system includes a device 110 and an integrated test circuit 180. The system 100 may include more than these components.

The device 110 is semiconductor device. In one embodiment, the device 110 is manufactured from a design and verification process using a hardware description language (HDL). Examples of the HDL are Verilog and Very-High-Speed Integrated Circuit Hardware Description Language (VHDL). The circuit designer uses the HDL to describe the behavior of a digital circuit with textual code, which can then be translated into hardware by synthesis tools. The process typically includes a code description, a logic verification, logic synthesis, and physical design. The circuit is described by a register transfer level (RTL) code. The RTL code describes the behavior and functionality of a digital circuit at an abstraction level, in terms of how data flows between registers and the operations performed on the data. The logic verification checks and confirm the function and the correctness of the design. In logic synthesis, the RTL description is converted into a gate-level netlist. In the physical design, a place-and-route (PNR) tool specifies where the circuit components are located on a chip and how they are connected. The design files are then sent to a manufacturer to fabricate the device.

The device 110 includes an internal circuit 120, other circuits 130, and part of an integrated test circuit 180. The device 110 may include more or less than the above components. The device 110 may be an actual device in silicon or an emulator that contains circuits that emulate the functionalities of the actual circuits

The internal circuit 110 is the circuit on which the testing is to be performed. It includes N logic circuits 140₁ to 140_{N}, M registers/flip-flops 150₁ to 150_{M}, a clock and control circuit 160, and a scandump storage 170. The internal circuit 110 may include more or less than the above components. The logic circuits 140₁ to 140_{N} are the circuits that perform the functions of the device. They may include logic operations such as gating (e.g., AND-OR), decoding, multiplexing, demultiplexing, etc. They may include combinational circuits and sequential circuits. They may produce outputs based on the inputs and control signals. The registers/flip-flops 150₁ to 150_{M} provide storage of the data. They may be part of sequential circuits. Part of the registers/flip-flops 150₁ to 150_{M} may correspond to anarea that reflect the core functionality of the device 110 and need to be checked or tested. These flip-flops may form a test pattern that can be observed and read out for checking.

The clock and control circuit 160 provide timing signals to all circuits and elements in the internal circuit 120. It can be controlled to stop generating clock signals to stop the device 110 including the internal circuit 120 to operate. It can also be enabled to generate the clock signals to start the device 110 and the internal circuit 120. The scandump storage 170 is a storage device that stores the scandump pattern as transferred from the internal circuit 110. It may be a part of a scan chain circuit that serially transfer the bits from the flip-flops and registers designated as part of the test circuit.

The other circuits 130 include circuit elements that are not part of the testing process. These may include any circuits or elements, flip-flops, registers, memory circuits, analog circuits, sensors, power circuits, etc. that are not subject to testing.

The partial part of the integrated test circuit 180 includes a scandump circuit 185 which is a circuit internal to the device 110 that is designed specifically to provide scandump operations for testing. The details of the scandump circuit 185 will be discussed later.

The integrated test circuit 180 includes components of a test assembly that is employed to test or verify the device 110. It interacts with a user 105. The integrated test circuit 180 includes an external test circuit 182 which is located externally to the device 110 and the scandump circuit 185 located internally to the device. The integrated test circuit may not include both the external test circuit 182 and the internal scandump circuit 185. In embodiments that use software simulation, the integrated test circuit 180 includes only the external test circuit 182. In embodiments that use both software and hardware, the integrated test circuit 180 includes both the external test circuit 182 and the internal scandump circuit 185. The simulation that performs in the combination of software and hardware may be referred to co-simulation or hybrid simulation.

The user 105 is an individual who performs the testing of the device 110. He or she may be a designer who wants to verify the functions of the device 110. He or she may interact with the integrated test circuit 180 via a processing or computing system which house the applications or software packages that provide the test sequence or the simulation.

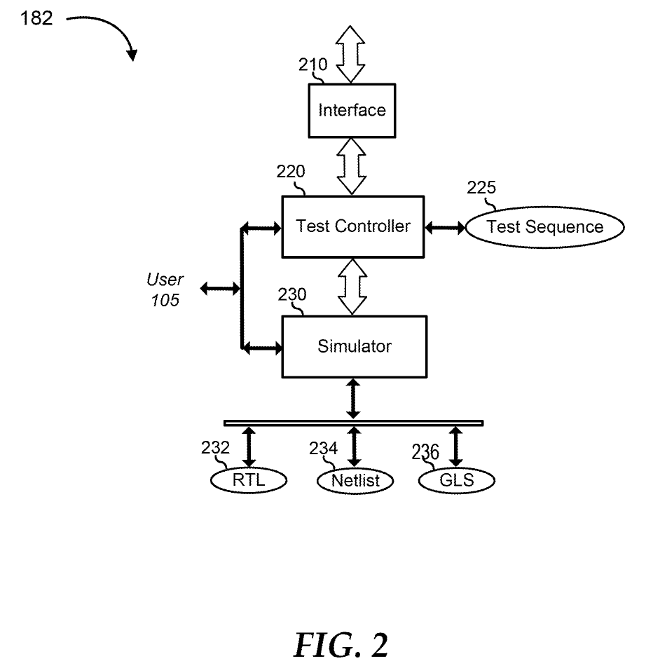

FIG. 2 is a diagram illustrating an external test circuit 182 according to an embodiment. The external test circuit 182 may be used in a software simulation mode or in a hybrid simulation mode. It includes elements that allow a testing using simulation to be performed. In one embodiment, it includes an interface circuit 210, a test controller 220, and a simulator 230. The external test circuit 182 may include more or less than the above components.

The interface circuit 210 is configured to communicate with the device 110 under test to obtain a test scandump from the scandump storage 170 which corresponds to the internal circuit 120 of the device 110. The interface circuit 210 may include a serial or parallel communication circuit to send information to the device 110 or to receive information including data, status, or test patterns from the device 110. In one embodiment, the interface circuit 210 may include a combination of parallel and serial input/output (IO) ports and other types such as Joint Test Action Group (JTAG) interface.

The test controller 220 is configured to: (1) generate a test sequence 225 to the interface 210 to control the device 110, and (2) enable a simulation performed by the simulator 230 having a design associated with the device 110. In one embodiment, the test sequence includes identifying a mismatch pattern between a final scan pattern from a final scandump and a simulation pattern from the simulation performed by the simulator 230. The mismatch pattern corresponds to a fault, which may by a stuck-at-fault or any other types of circuit fault. The test sequence 225 may be implemented as a number of script files, each contains a script that performs a specific task. The scripts may be written in an appropriate language and translated by a translator into a sequence of commands to be transferred to and executed in the device 110.

The simulator 230 is a software program that is used to design the device 110. Its functional behavior is therefore theoretically identical to that of the device 110. The simulator 230 is not subject to wear-out, environmental effect, or any physical conditions that the device 110 may be subject to. Therefore, when it performs the simulation that tests the device 110, the result of a simulation may serve as a golden truth to verify the internal circuit 120.

The simulation may be performed using an RTL simulation 232, a netlist simulation 234, or a gate-level simulation (GLS) 236. In the netlist simulation 234, a netlist is used. A netlist is a textual description of an electronic circuit, describing all the connections of all the circuit elements in the device 110 including the internal circuit 120. It provides the framework for a simulation software to analyze the circuit behavior and function by defining the connectivity between different components. The simulator 230 may be a simulation program that is used to design and verify electronic circuits. An example is the Simulation Program with Integrated Circuit Emphasis (SPICE). In the RTL simulation 232, the environment operates with zero delays, and events primarily occur at the active clock edge. In the GLS 236, the netlist representation provides a comprehensive list of connections, including gates and intellectual property (IP) models, along with their complete functional and timing characteristics.

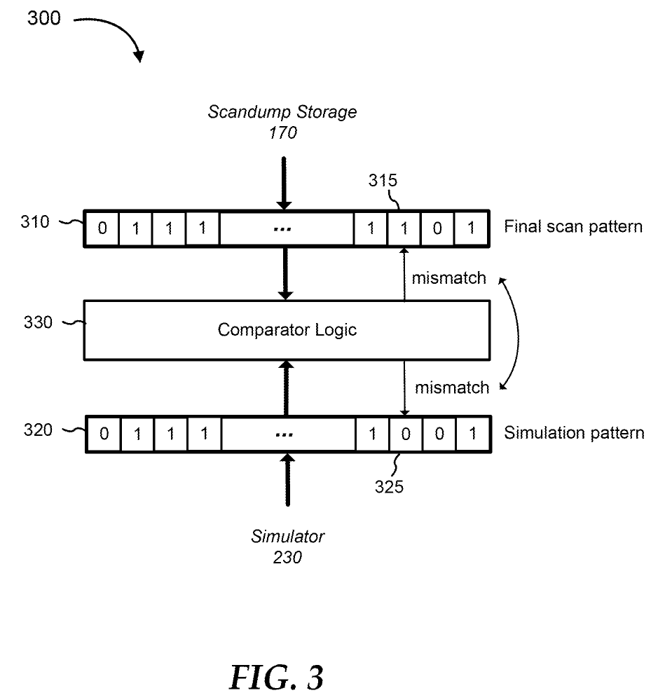

FIG. 3 is a diagram illustrating a comparison 300 of a final scan pattern and a simulation pattern according to an embodiment. The comparison 300 includes a final scan pattern 310, a simulation pattern 320 and a comparator logic 330. The simulation pattern may represent a snapshot of the simulation at a specified instant that corresponds to the same time instant in terms of clock cycles that have passed in the internal circuit 120. The final scan pattern 310 is the bit pattern obtained from the scandump storage 170 after the internal circuit 120 is allowed to run for a specified number of clock cycles. The simulation pattern 320 is the bit pattern obtained from the simulator 230 after a simulation that simulates the internal circuit 120 using the same stimulus or triggering condition and operating for the same specified number of clock cycles. The stimulus or triggering condition may include the bit pattern of the inputs to the components in the internal circuit 120. The final scan pattern 310 and the simulation pattern 320 may be in forms of bitstreams that are read serially and the comparator logic 330 compares the two bitstreams one bit at a time. The exact nature of the pattern format, whether serial or parallel, is not important as long as the two patterns can be compared to identify any mismatch.

The comparator logic 330 is a circuit or a function that compares the final scan pattern 310 and the simulation pattern 320 to determine if there is any mismatch. Since the simulation pattern 320 is the result of a simulation of the internal circuit 120 under the same conditions as the internal circuit 120, it should be ideally identical to the final scan pattern 310. Accordingly, any mismatch indicates a fault condition in the internal circuit 120. In the example shown in FIG. 3, bit 315 of the final scan pattern 310 and bit 325 of the simulation pattern 320 do not match. This mismatch indicates that one of the bits is wrong. Since the simulation is assumed to be the ground truth, the conclusion is that bit 315 of the final scan pattern 310 is incorrect.

Once the mismatched bit is identified, its actual location in the internal circuit 120 may be traced and identified. This will lead to an examination of the circuit in that area to determine the cause of the fault.

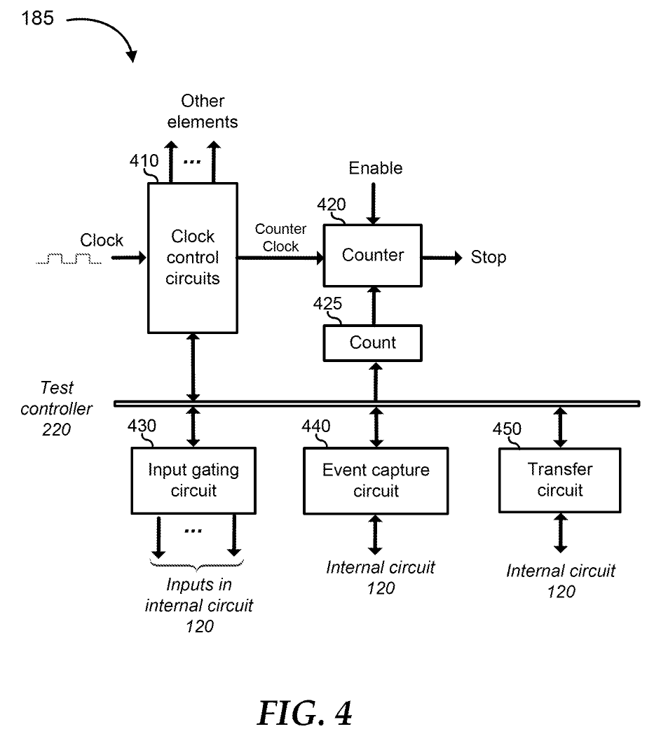

FIG. 4 is a diagram illustrating the scandump circuit 185 according to an embodiment. The scandump circuit 185 is located internally to the device 110 and is configured to provide timing and control signals to match with functionalities of the simulator 230. It is designed specifically to test the internal circuit 120. It is located inside the device 110 to have access to various locations of the flip-flops or registers in the internal circuit 120 that need to be checked out. The scandump circuit 185 is used only in the hybrid mode. The simulation by software only may allow the simulator to enable the device to run for some predefined number of cycles and to stop the device, but it may not provide the flexibility of having access to certain locations in the circuit, provide a specified input pattern to drive the circuit, or capture a certain event in the circuit. The scandump circuit 185 is located internally to the device 110 and is configured to provide timing and control signals to match with functionalities of the simulator The scandump circuit 185 includes a clock control circuit 410, a counter 420, an input gating circuit 430, an event capture circuit 440, and a transfer circuit 450. All of these components are controlled by the test controller 220. The scandump circuit 185 may include more or less than the above components.

The clock control circuit 410 is configured to control a clock signal that provides the timing signals to the internal circuit. The clock control circuit 410 may be controlled by the test controller 220 to start or stop the clock as a way to star or stop, respectively, the internal circuit 120. The counter 420 is configured to assert a stop signal when a count is reached. It is clocked by the clock signal. It is cleared (or reset) and enabled by counter control signal from the clock control circuits 410. The stop signal, when asserted, indicates that certain period or a number of clock cycles has been passed since the counter starts counting. The counter 420 may be set in a count-down mode or a count-up mode. In the count-down mode, initially the stop signal is de-asserted or negated (e.g., set to zero), and the counter is loaded with an initial count in a count register 425. The counter is then enabled to count down until it reaches zero. When it reaches zero, the stop signal is asserted (e.g., set to one) indicating that the time specified by the count register 425 has expired. In a count-up mode, the counter is set to zero initially and the count register 425 is initially loaded with the final count value. Its output is compared with the final count value in the count register 425. When the two values are the same, the stop signal is asserted. By having the count register 425 and the stop signal, the counter 420 can be used to control the internal circuit 120 to operate or run in a specified number of clock cycles.

The input gating circuit 430 is configured to capture activities at inputs of the internal circuit in an input enable mode and disable the inputs in an input disable mode. The input gating circuit 430 allows control the inputs of certain registers or flip-flops that are inputs to other circuits. For example, it may pre-load the inputs with predetermined values, or it may disable the inputs so that the inputs do not affect the operation of the internal circuit 120.

The event capture circuit 440 is configured to capture an event related to the simulation. The captured event may be a triggering condition to start or stop a sequence of operations. Examples of an event are: a specified output is produced at a specified register, an overflow condition, an invalid input, etc.

The transfer circuit 450 is configured to transfer outputs of the internal circuit to the scandump storage 170. The transfer circuit 450 may be derived from the internal scan chain circuit or a new circuit that transfer the contents of the serial scan circuit into the scandump storage 170 to be read by the integrated test circuit 180.

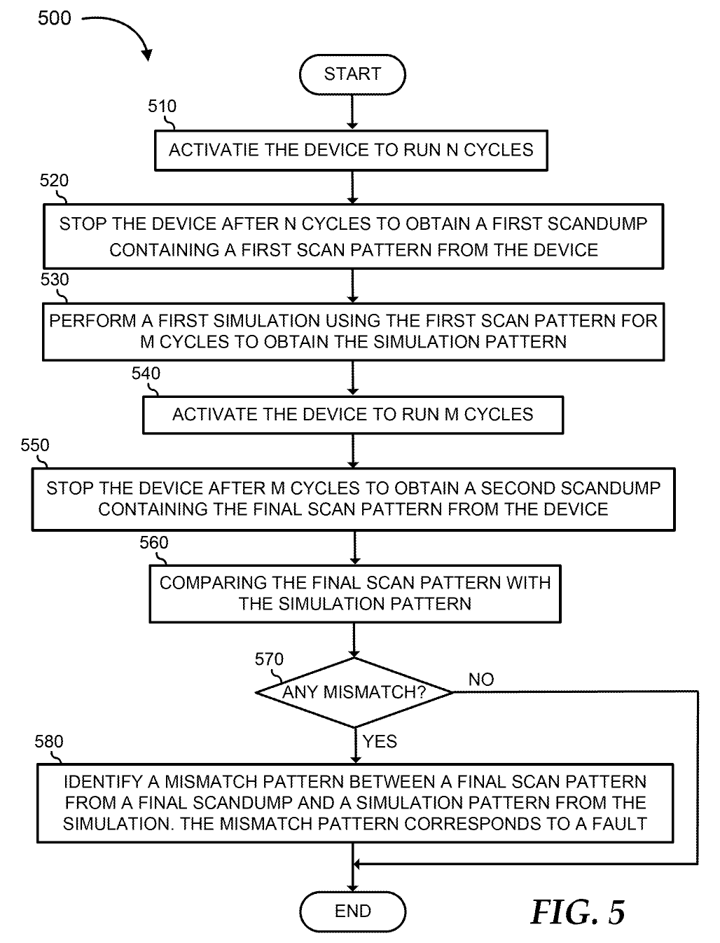

FIG. 5 is a flowchart illustrating a process 500 of testing with simulation according to an embodiment. The process 500 is mainly about the simulation by software. The process 500 may be implemented by a script having several commands to perform the specified operations.

Upon START, the process 500 activates the device to run N cycles (Block 510). Then, the process 500 stops the device after N cycles to obtain a first scandump containing a first scan pattern from the device (Block 520). Next, the process 500 performs a first simulation using the first scan pattern for M cycles to obtain the simulation pattern (Block 530). The first scan pattern is used as the stimulus or initial input pattern for the simulation. Then, the process 500 activates the device again to run M cycles (Block 540). Therefore, the simulation and the device operates from the same starting condition by having the same first scan pattern. The implication is that since they operate from the same input or initial condition, they should produce identical results or outputs.

Next, the process 500 stops the device after M cycles to obtain a second scandump containing the final scan pattern from the device (Block 550). Then, the process 500 compares the final scan pattern with the simulation pattern (Block 560). As mentioned above, the final scan pattern and the simulation pattern are ideally identical. Next, the process 500 determines if there is any mismatch between the final scan pattern and the simulation pattern (Block 570). If there is no mismatch (NO branch at block 570), the process 500 is terminated because the device passes the simulation test. If there is a mismatch (YES at block 570), the process 500 identifies the mismatch pattern which corresponds to a fault (Blocks 580) and is then terminated.

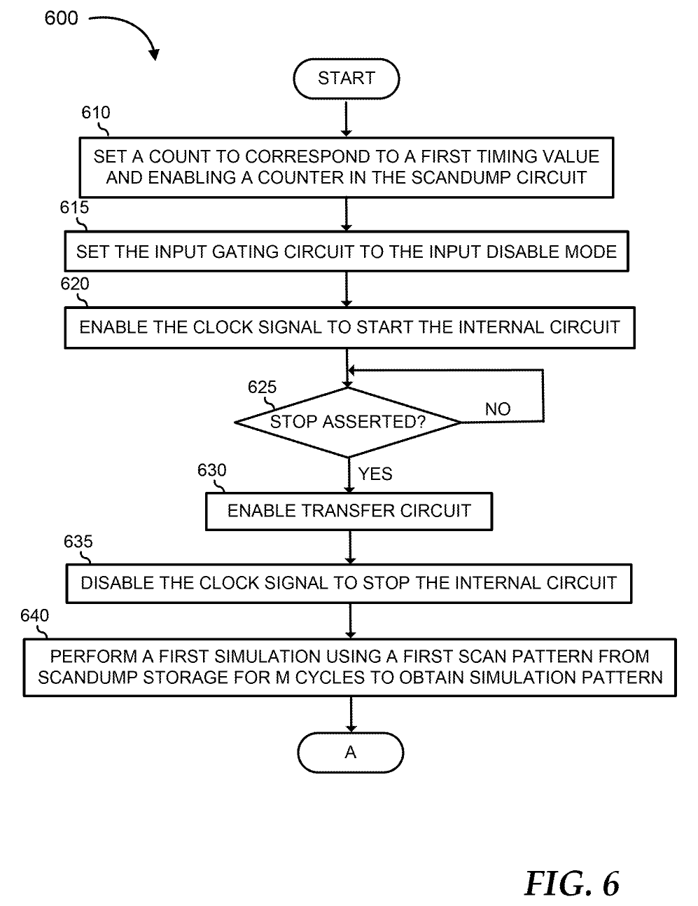

FIG. 6 is a flowchart illustrating the first part of a process 600 of testing with scandump circuit and simulation according to an embodiment. The process 600 is mainly about the hybrid simulation in which both the simulator 230 and the scandump circuit 185 are deployed during the testing process. The process 600 may be implemented by a script having several commands to perform the specified operations.

Upon START, the process 600 sets the count for the counter 420 to correspond to a first timing value and enables the counter (Block 610). The setting also configures the counter 420 in an appropriate mode, either count-up or count-down. Once enabled, the counter 420 starts counting. Next, the process 600 sets the input gating circuit to the input disable mode (Block 615). This is to ensure that the inputs to the internal circuits are not changing during the simulation. Then, the process 600 enables the clock signal to start the internal circuit 120 (Block 620).

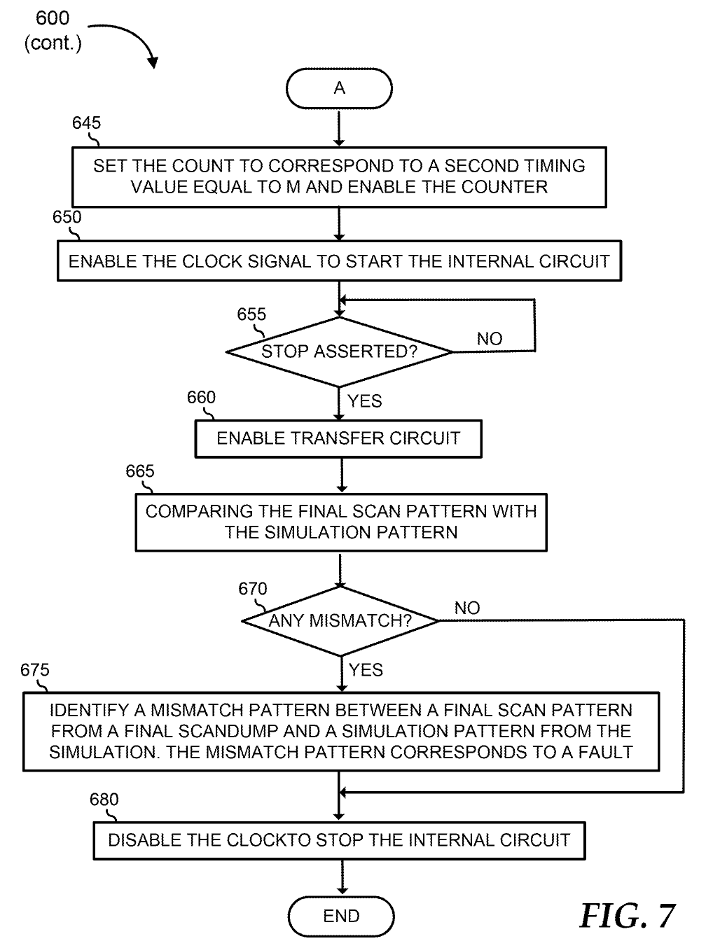

Next, the process 600 determines if the counter asserts a stop signal (Block 625). If not, the process 600 loops back to block 625 and continues to check for the stop signal. In practice, there is no actual looping back because the counter 420 is a free-running device. It will assert the stop signal when it reaches the preset value. This value is zero if it is set in count-down mode. Otherwise, if the counter asserts the stop signal, the process 600 enables the transfer circuit (Block 630). This will transfer the value of the scan pattern to the scandump storage 170. Next, the process 600 disables the clock signal to stop the internal circuit (Block 635). This is to keep the internal circuit 120 to be at the same state as the simulation that follows. Then, the process 600 performs a first simulation using a first scan pattern from the scandump storage for M cycles to obtain a simulation pattern (Block 640). This is to ensure that the internal circuit 120 and the simulation have the same starting condition. Next, the process 600 proceeds to point A which will continue in FIG. 7.

FIG. 7 is a flowchart illustrating the second part of the process 600 of testing with scandump circuit and simulation according to an embodiment. Most of the operations are similar to those in FIG. 6.

Upon continuing at point A, the process 600 sets the count to correspond to a second timing value equal to M and enables the counter (Block 645). Next, the process 600 enables the clock signal to start the internal circuit 120 (Block 650). Then, the process 600 determines if the counter asserts the stop signal (Block 655). Again this operation does not require an explicit checking operation because the counter will generate the stop signal when the counter reaches the preset value. If not, the process 600 loops back to block 655 and continues to check for the stop signal in a similar manner as in block 625. Otherwise, when the counter asserts the stop signal (YES at block 655), the process 600 enables the transfer circuit (Block 660).

Then, the process 600 compares the final scan pattern from the scandump storage with the simulation pattern (Block 665). Next, the process 600 determines if there is any mismatch between the final scan pattern and the simulation pattern (Block 670). If there is no mismatch (NO branch at block 670), the process 500 proceeds to block 680 because the device passes the simulation test. If there is a mismatch (YES at block 670), the process 600 identifies the mismatch pattern which corresponds to a fault (Blocks 675). The process 600 next disables the clock signal to stop the internal circuit (Block 680) and is then terminated.

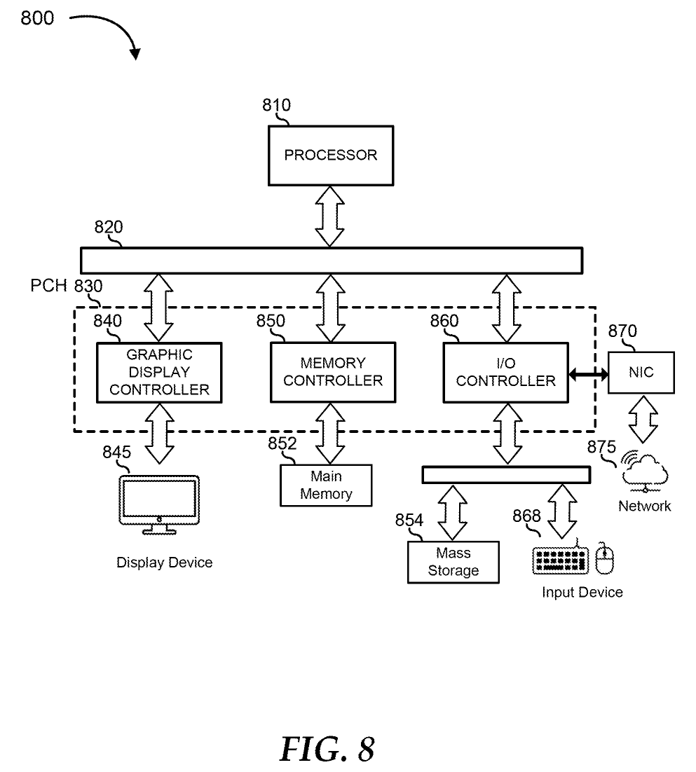

FIG. 8 is a diagram illustrating a processing or computing system 800 according to an embodiment.

The processing system or computing system 800 may be a host in a system on which the external test circuit 182 or the simulator 230 operates. It includes a central processing unit (CPU) or a processor 810, a platform controller hub (PCH) 830, and a bus 820. The PCH 830 may include a graphic display controller (GDC) 840, a memory controller 850, and an input/output (I/O) controller 860. The processing system 800 may include more or less than the above components. In addition, a component may be integrated into another component. As shown in FIG. 8, all the controllers 840, 850, and 860 are integrated in the PCH 830. The integration may be partial and/or overlapped. For example, the GDC 840 may be integrated into the processor 810, the I/O controller 860 and the memory controller 850 may be integrated into one single controller, etc.

The processor 810 is a programmable device that may execute a program or a collection of instructions to carry out a task. It may be a general-purpose processor, a digital signal processor, a microcontroller, or a specially designed processor such as one design from Applications Specific Integrated Circuit (ASIC). It may include a single core or multiple cores. Each core may have multi-way multi-threading. The processor 810 may have simultaneous multithreading feature to further exploit the parallelism due to multiple threads across the multiple cores. In addition, the processor 810 may have internal caches at multiple levels.

The bus 820 may be any suitable bus connecting the processor 810 to other devices, including the PCH 830. For example, the bus 820 may be a Direct Media Interface (DMI).

The PCH 830 in a highly integrated chipset that includes many functionalities to provide interface to several devices such as memory devices, input/output devices, storage devices, network devices, etc.

The I/O controller 860 controls input devices 868 (e.g., stylus, keyboard, and mouse, microphone, image sensor) and output devices (e.g., audio devices, speaker, scanner, printer), and a mass storage 854. The mass storage 854 may also include CD-ROM, hard disk, and solid-state drives (SSDs(. The SSDs may be used with the vector database 120 as described above. It also has a network interface card (NIC) 870 which provides interface to a network and wireless medium 875.

The memory controller 850 controls memory devices such as a main memory 852. The main memory 852 includes random access memory (RAM) and/or the read-only memory (ROM) and other types of memory such as the cache memory or an SSD. The main memory 852 may store instructions or programs, loaded from a mass storage device, that, when executed by the processor 810, cause the processor 810 to perform operations as described above. It may also store data used in the operations. The ROM may include instructions, programs, constants, or data that are maintained whether it is powered or not. The instructions or programs may correspond to the functionalities described above, such as the test controller 220 or the simulator 230.

The GDC 840 controls a display device 845 and provides graphical operations. It may be integrated inside the processor 810. It typically has a graphical user interface (GUI) to allow interactions with a user who may send a command or activate a function.

Additional devices or bus interfaces may be available for interconnections and/or expansion. The bus interfaces may be serial or parallel, with or without power delivery, etc.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A test circuit comprising:
an interface circuit configured to communicate with a device under test to obtain a test scandump from a scandump storage corresponding to an internal circuit of the device; and
a test controller configured to generate a test sequence to the interface circuit to control the device and enable a simulation performed by a simulator having a design associated with the device;
wherein the test sequence includes identifying a mismatch pattern between a final scan pattern from a final scandump and a simulation pattern from the simulation, the mismatch pattern corresponding to a fault.

2. The test circuit of claim 1, wherein the test sequence further comprises:
activating the device to run N cycles;
stopping the device after N cycles to obtain a first scandump containing a first scan pattern from the device;
performing a first simulation using the first scan pattern for M cycles to obtain the simulation pattern;
activating the device to run M cycles;
stopping the device after M cycles to obtain a second scandump containing the final scan pattern from the device; and
comparing the final scan pattern with the simulation pattern.

3. The test circuit of claim 1, further comprising:
a scandump circuit located internally to the device and configured to provide timing and control signals to match with functionalities of the simulator.

4. The test circuit of claim 3, wherein the scandump circuit comprises:
a clock control circuit configured to control a clock signal that provides the timing signals to the internal circuit;
a counter configured to assert a stop signal when a count is reached, the counter being clocked by the clock signal;
an input gating circuit configured to capture activities at inputs of the internal circuit in an input enable mode and disable the inputs in an input disable mode;
an event capture circuit configured to capture an event related to the simulation; and
a transfer circuit configured to transfer outputs of the internal circuit to the scandump storage.

5. The test circuit of claim 4, wherein the test sequence further comprises:
setting the count to correspond to a first timing value and enabling the counter;
setting the input gating circuit to the input disable mode;
enabling the clock signal to start the internal circuit; and
when the stop signal is asserted,
enabling the transfer circuit,
disabling the clock signal to stop the internal circuit, and
performing a first simulation using a first scan pattern from the scandump storage for M cycles to obtain the simulation pattern.

6. The test circuit of claim 5, wherein the test sequence further comprises:
setting the count to correspond to a second timing value equal to M and enabling the counter;
enabling the clock signal to start the internal circuit;
enabling the transfer circuit when the stop signal is asserted; and
comparing the final scan pattern from the scandump storage with the simulation pattern.

7. The test circuit of claim 6, wherein the test sequence further comprises:
disabling the clock signal to stop the internal circuit.

8. The test circuit of claim 4, wherein the fault is one of a stuck-at-0 fault, a stuck-at-1 fault, a bit flip fault, and an at-speed fault.

9. The test circuit of claim 1, wherein the device is a semiconductor device.

10. The test circuit of claim 1, wherein the simulator is one of a register transfer language (RTL) simulator, a netlist simulator, and a gate-level simulator.

11. A method comprising:
communicating, by an interface circuit, with a device under test to obtain a test scandump from a scandump storage corresponding to an internal circuit of the device; and
generating, by a test controller, a test sequence to the interface circuit to control the device and enabling a simulation performed by a simulator having a design associated with the device;
wherein the test sequence includes identifying a mismatch pattern between a final scan pattern from a final scandump and a simulation pattern from the simulation, the mismatch pattern corresponding to a fault.

12. The method of claim 11, wherein the test sequence further comprises:
activating the device to run N cycles;
stopping the device after N cycles to obtain a first scandump containing a first scan pattern from the device;
performing a first simulation using the first scan pattern for M cycles to obtain the simulation pattern;
activating the device to run M cycles;
stopping the device after M cycles to obtain a second scandump containing the final scan pattern from the device; and
comparing the final scan pattern with the simulation pattern.

13. The method of claim 11, further comprising:
providing timing and control signals by a scandump circuit located internally to the device to match with functionalities of the simulator.

14. The method of claim 13, wherein providing timing and control signals comprises:
controlling a clock signal, by a clock control circuit, that provides the timing signals to the internal circuit;
asserting a stop signal, by a counter, when a count is reached, wherein the counter is clocked by the clock signal;
capturing, by an input gating circuit, activities at inputs of the internal circuit in an input enable mode and disable the inputs in an input disable mode;
capturing, by the event capture circuit, an event related to the simulation; and
transferring, by a transfer circuit, outputs of the internal circuit to the scandump storage.

15. The method of claim 14, wherein the test sequence further comprises:
setting the count to correspond to a first timing value and enabling the counter;
setting the input gating circuit to the input disable mode;
enabling the clock signal to start the internal circuit; and
when the stop signal is asserted,
enabling the transfer circuit,
disabling the clock signal to stop the internal circuit, and
performing a first simulation using a first scan pattern from the scandump storage for M cycles to obtain the simulation pattern.

16. The method of claim 15, wherein the test sequence further comprises:
setting the count to correspond to a second timing value equal to M and enabling the counter;
enabling the clock signal to start the internal circuit;
enabling the transfer circuit when the stop signal is asserted; and
comparing the final scan pattern from the scandump storage with the simulation pattern.

17. The method of claim 16, wherein the test sequence further comprises:
disabling the clock signal to stop the internal circuit.

18. The method of claim 14, wherein the fault is one of a stuck-at-0 fault, a stuck-at-1 fault, a bit flip fault, and an at-speed fault.

19. The method of claim 11, wherein the simulator is one of a register transfer language (RTL) simulator, a netlist simulator, and a gate-level simulator.

20. A system comprising:
a semiconductor device; and
a test circuit to test the device, comprising:
an interface circuit configured to communicate with the device to obtain a test scandump from a scandump storage corresponding to an internal circuit of the device; and
a test controller configured to generate a test sequence to the interface circuit to control the device and enable a simulation performed by a simulator having a design associated with the device;
wherein the test sequence includes identifying a mismatch pattern between a final scan pattern from a final scandump and a simulation pattern from the simulation, the mismatch pattern corresponding to a fault.
